(19) United States
(12) Patent Application Publication
(10) Pub. No.: US 2003/0146492 A1
(43) Pub. Date: Aug. 7, 2003

(54) Nitride etchstop film to protect metal-insulator-metal capacitor dielectric from degradation and method for making same

(75) Inventors: John Chester Malinowski, Jericho, VT (US); Matthew David Moon, Jeffersonville, VT (US); Vidhya Ramachandran, Colchester, VT (US); Kimball M. Watson, Essex Junction, VT (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 10/065,843

(22) Filed: Nov. 25, 2002

Related U.S. Application Data
(60) Provisional application No. 60/354,882, filed on Feb. 5, 2002.

(51) Int. Cl. H01L 21/20; H01L 29/00; H01L 21/302; H01L 21/461

(52) U.S. Cl. 257/532; 438/396; 438/744; 438/757

(57) ABSTRACT

A multilayer semiconductor device that includes a metal-insulator-metal (MIM) capacitor including a first metal plate, a dielectric layer, and a second metal plate, a nitride etchstop layer formed above the MIM capacitor, a first interlayer dielectric formed on the nitride etchstop layer, and a first via and a second via that extend through at least the first interlayer dielectric to contact the nitride etchstop layer.

### CROSS REFERENCE TO RELATED APPLICATIONS

This application is based on Provisional Application No. 60/354,882, filed on Feb. 5, 2002.

### BACKGROUND OF THE INVENTION

1. Field of the Invention

The present invention generally relates to a metal-insulator-metal (MIM) capacitor in a semiconductor device and a method of fabricating the same. More particularly, this invention relates to the use of a nitride etchstop layer to prevent degradation of the dielectric of the MIM capacitor.

2. Description of the Related Art

In a multilayer semiconductor, when vias are formed to contact the metal plates of an MIM capacitor, greater control of forming the vias and maintaining a shape of the via are obtained by using an anisotropic etch process, such as, reactive ion etching (RIE), as opposed to an isotropic etching process, such as, a wet chemical etch. RIE is particularly useful for forming vias when the depth and corresponding aspect ratio of the via are relatively large. However, forming vias that contact the capacitor plates of an MIM capacitor by RIE and other anisotropic etch processes, which use ions and/or plasma, can produce degradation of the capacitor dielectric and even plate-to-plate electrical shorting of the MIM capacitor.

Dielectric breakdown is caused by excessive electrical charge build-up across the plates, which may result from an aggressive RIE etch that lands a via on the top plate of the MIM capacitor or other anisotropic etch processes that are performed at levels above the MIM capacitor. Dielectric breakdown results from permanent conductive channels being formed in the dielectric, which degrade the insulative properties of the dielectric.

Plate-to-plate electrical shorting of the MIM capacitor results from either top plate etch-through by an aggressive RIE etch that lands on the top plate or by dielectric breakdown caused by aggressive anisotropic etching above the MIM capacitor that causes electrical shorting across the dielectric layer.

Degradation of long term reliability of the dielectric layer of the MIM capacitor is measured by time dependent dielectric breakdown, where the time to breakdown is measured under a constant electric field of about 6-9 MV/cm. The conventionally fabricated MIM capacitor dielectric layer often shows degradation of long term reliability, when compared to the expected lifetime of a comparable defect-free dielectric layer.

During conventional fabrication of a multilayer semiconductor device including an MIM capacitor, RIE etch processes that cause dielectric degradation include: RIE patterning of the top plate of the MIM capacitor, that is, the Q etch; RIE via etch processes that create vias that land on the top and/or bottom plates of the MIM capacitor; and other anisotropic etch processes that take place above the MIM capacitor subsequent to completion of the MIM capacitor processing, such as, pattern etching of a wiring level in electrical contact with the top and/or bottom plates.

Via formation by RIE requires overetch in order to ensure proper landing of the via on both the top and bottom plate. This overetch exposes the top and bottom capacitor plates to a longer duration and a greater magnitude of electrical charge and ion/plasma damage, associated with the RIE. However, since the top plate is landed on first, the top plate experiences greater electrical charging and more ion/plasma damage from the effects of this overetch.

### BRIEF SUMMARY OF THE INVENTION

In view of the foregoing and other problems and disadvantages of conventional methods, an advantage of the present invention is the extended lifetime of an MIM capacitor dielectric within a multilayer semiconductor device that may be attained by depositing a nitride etchstop layer above the MIM capacitor to prevent degradation of the capacitor dielectric, which may be caused by excessive electrical charging and ion/plasma damage of the plates of the MIM capacitor by anisotropic etch processes.

Another advantage of the present invention is preventing plate-to-plate electrical shorting of the MIM capacitor within a multilayer semiconductor device, which may be caused by either top plate etch-through or dielectric breakdown, associated with anisotropic etch processes above the level of the MIM capacitor.

A further advantage of the present invention is providing a method of fabricating an MIM capacitor within a multilayer semiconductor device by standard semiconductor fabrication processes that may offer improved yields and enhanced long term reliabiltiy.

In order to attain the above and other advantages, according to an exemplary embodiment of the present invention, disclosed herein is a multilayer semiconductor device comprising a metal-insulator-metal (MIM) capacitor that includes a first metal plate, a dielectric layer, and a second metal plate, a nitride etchstop layer formed above the MIM capacitor, a first interlayer dielectric formed on top of the nitride etchstop layer, and a first via and a second via that extend through at least the first interlayer dielectric to contact the nitride etchstop layer.

According to another exemplary embodiment of the present invention, the nitride etchstop layer is deposited directly upon the MIM capacitor.

According to another exemplary embodiment of the present invention, the first metal plate and the second metal plate correspond to a bottom plate and a top plate of the MIM capacitor, respectively.

According to another exemplary embodiment of the present invention, the multilayer semiconductor device further comprises a second interlayer dielectric formed between the top plate of the MIM capacitor and the nitride etchstop layer.

According to another exemplary embodiment of the present invention, the second interlayer dielectric comprises a thickness of about 1500 Ã . . . to about 10,000 Ã. . . .

According to another exemplary embodiment of the present invention, the thickness of the nitride etchstop layer is about 500Ã . . . to about 1500 Ã. . . .

According to another exemplary embodiment of the present invention, a thickness of the nitride etchstop layer is about 700 Ã . . . to about 1200 Ã. . . .

According to another exemplary embodiment of the present invention, the multilayer semiconductor device further comprises a wiring level that is electrically connected to at least one of the first metal plate and the second metal plate.

According to another exemplary embodiment of the present invention, a method of fabricating a multilayer semiconductor device comprises forming an MIM capacitor that includes a first metal plate, a dielectric layer formed on the first metal plate, and a second metal plate formed on the dielectric layer, patterning the second metal plate, depositing a nitride etchstop layer above the MIM capacitor, forming a first interlayer dielectric on the nitride etchstop layer, forming a first via and a second via through at least the first interlayer dielectric by an anisotropic etch process to contact the nitride etchstop layer above the patterned second metal plate and above the first metal plate, respectively, and removing portions of the nitride etchtop layer, where the first via and the second via contact the nitride etchstop layer.

According to another exemplary embodiment of the present invention, patterning the second metal plate is accomplished by an anisotropic etch process.

According to another exemplary embodiment of the present invention, the selective via etch chemistry may include any of the group of argon, nitrogen, C4F8 and argon or oxygen, and carbon monoxide.

According to another exemplary embodiment of the present invention, the depositing of the nitride etchstop layer is directly upon the MIM capacitor.

According to another exemplary embodiment of the present invention, the method of fabricating the multilayer semiconductor device further comprises patterning at least one of the first metal plate and the dielectric layer by the anisotropic etch process.

According to another exemplary embodiment of the present invention, the method of fabricating a multilayer semiconductor device further comprises patterning a wiring level in electrical contact with at least one of the first metal plate and the second metal plate by an anisotropic etch process.

According to another exemplary embodiment of the present invention, the method of fabricating the multilayer semiconductor device further comprises forming a second interlayer dielectric between the second metal plate and the nitride etchstop layer.

According to another exemplary embodiment of the present invention, the method of fabricating a multilayer semiconductor device, including an MIM capacitor, comprises patterning a metal top plate of the MIM capacitor by an anisotropic etch process, depositing a nitride etchstop layer above the MIM capacitor, forming a first interlayer dielectric on the nitride etchstop layer, and forming a first via through the first interlayer dielectric by an anisotropic etch process to contact the nitride etchstop layer.

According to another exemplary embodiment of the present invention, the method of fabricating the multilayer semiconductor device, including an MIM capacitor, further comprises removing a first portion of the nitride etchstop layer above the MIM capacitor, so that, the first via contacts the metal top plate.

According to another exemplary embodiment of the present invention, the method of fabricating the multilayer semiconductor device, including an MIM capacitor, further comprises forming a second via through the first interlayer dielectric by an anisotropic etch process to contact the nitride etchstop layer.

According to another exemplary embodiment of the present invention, the method of fabricating the multilayer semiconductor device, including an MIM capacitor, further comprises removing a second portion of the nitride etchstop layer above the MIM capacitor, so that, the second via contacts a metal bottom plate of the MIM capacitor.

According to another exemplary embodiment of the present invention, the method of fabricating the multilayer semiconductor device, including an MIM capacitor, further comprises forming a second interlayer dielectric between the metal top plate and the nitride etchstop layer.

Thus, the present invention overcomes the problems of the conventional methods and structures of an MIM capacitor disposed within a multilayer semiconductor device by using a nitride etchstop film that may prevent either dielectric breakdown of an MIM capacitor, associated with anisotropic etching at levels above the MIM capacitor, or plate-to-plate electrical shorting, caused by etch-through of the top plate. The present invention also enhances the long term reliability of an MIM capacitor, when compared to conventional fabrication methods by depositing an insulating nitride film above the MIM capacitor, which may reduce dielectric degradation caused by excessive electrical charging of the MIM capacitor during anisotropic process above the MIM capacitor.

### BRIEF DESCRIPTION OF THE SEVERAL VIEWS OF THE DRAWINGS

The foregoing and other aspects and advantages will be better understood from the following detailed description of a preferred embodiment of the invention with reference to the drawing, in which:

FIG. 1 illustrates a multilayer semiconductor device 100 in an exemplary embodiment of the present invention; and

FIG. 2 illustrates a flowchart of a method for making the multilayer semiconductor device 100 of FIG. 1 in an exemplary embodiment of the present invention.

### DETAILED DESCRIPTION OF THE INVENTION

Generally, the present invention takes advantage of depositing a nitride etchstop layer above an MIM capacitor, which is included in a multilayer semiconductor device, to prevent dielectric degradation of the capacitor dielectric by anisotropic etching processes taking place above the MIM capacitor.

In various exemplary embodiments, the deposition of the nitride etchstop layer may occur after patterning the top plate of the MIM capacitor, after patterning the MIM capacitor and a wiring level electrically connected to the MIM capacitor, and after a thin intervening interlayer dielectric is deposited between the patterned top plate and the nitride etchstop layer. The nitride etchstop layer may provide an insulative layer, which may prevent electrical charge from reaching the plates of the MIM capacitor during an anisotropic etch occurring above the MIM capacitor and may also provide a layer upon which an anisotropic etch process is stopped. The dielectric layer of the MIM capacitor may, thus, attain better integrity and the long term reliability of the MIM capacitor may also be enhanced. The nitride etchstop layer may also prevent plate-to-plate electrical shorting by stopping etch-through of the top plate and prevent breakdown of insulative properties of the dielectic.

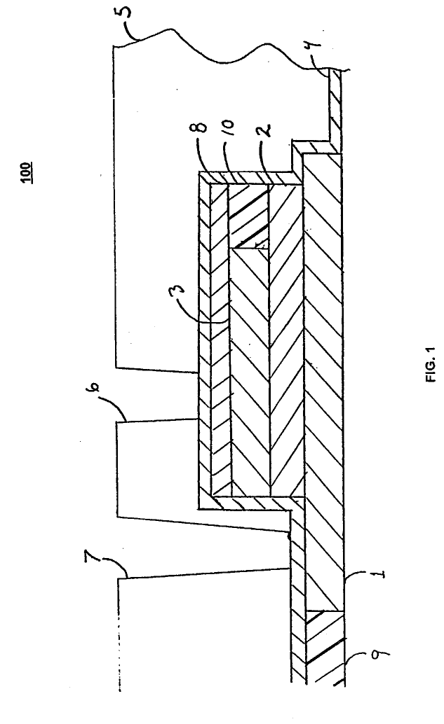

Referring to FIG. 1, a first metal plate 1 of an MIM capacitor may be formed above a semiconductor substrate of a multilayer semiconductor device 100. The first metal plate 1 may be deposited by, for example, sputtering, plating, polishing, and other metal deposition processes well known in the art. The first metal plate 1 may be electrically connected to a wiring level 9. The first metal plate 1 may be made of aluminum, copper, titanium nitride, tantalum nitride, and other metals and alloys of these metals well known in the art. The first metal plate 1 may have a thickness of about 500 Ã . . . to about 15,000 Ã . . . and may have an area of about 0.0001 mm to about 1 mm

In various exemplary embodiments, the first metal plate 1 may be patterned by conventional etch processes. Further, the first metal plate 1 may form a portion of a metal wiring level 9 and the first metal plate 1 and its corresponding wiring level 9 may both be patterned by, for example, an isotropic etch process.

A dielectric layer 2 of the MIM capacitor may be formed over the first metal plate 1 by conventional photomasking and deposition processes, for example, chemical vapor deposition (CVD), plasma enhanced CVD, atomic layer CVD, organometallic CVD, and other deposition processes well known in the art. The dielectric layer 2 may be made of silicon oxide, silicon nitride, silicon oxynitride, tantalum pentoxide, aluminum oxide, titanium oxide, and other dielectric materials well known in the art. The dielectric layer 2 may have a thickness of about 50 Ã . . . to about 1200 Ã. . . .

A second metal plate 3 of the MIM capacitor is formed above the dielectric layer 2. The second metal plate 3 may be deposited by, for example, sputtering, and other metal deposition processes well known in the art. The second metal plate 3 may be electrically connected to a wiring level 10. The second metal plate 3 may be made of aluminum, copper, titanium nitride, tantalum nitride, and other metals and alloys of these metals well known in the art. The second metal plate 3 may have a thickness of about 500 Ã . . . to about 5000 Ã . . . and usually has an area less than that of the first metal plate 1.

In various exemplary embodiments, the second metal plate 3 may be patterned by an anisotropic etch process, such as, for example, RIE. In various exemplary embodiments, the second metal plate 3 may form a portion of a metal wiring level 10 and the second metal plate 3 and its corresponding wiring level 10 may both be patterned by, for example, an anisotropic etch process.

A nitride etchstop layer 4 is formed above the MIM capacitor by, for example, plasma enhanced CVD (PECVD), atomic layer CVD, organometallic CVD, or other deposition processes well known in the art. In various exemplary embodiments, the thickness of the nitride etchstop layer may be from about 500 Ã . . . to about 1500 Ã . . . with a preferred thickness of about 700 Ã. . . .

In various exemplary embodiments, deposition of the nitride etchstop layer 4 may occur, for example, after the second metal plate 3 of the MIM capacitor has been patterned, after the MIM capacitor and an associated wiring level has been patterned, and optionally, after a relatively thin second interlayer dielectric 8 of about 1500 Ã . . . to about 10,000 Ã . . . has been deposited on the MIM capacitor, subsequent to the patterning of the MIM capacitor.

A first interlayer dielectric 5 may be formed above the nitride etchstop layer 4 by, for example, CVD, PECVD, and other dielectric deposition processes well known in the art. The first interlayer dielectric 5 may be made of silicon oxide, fluorinated silicon oxide, SiLK, and other dielectric materials well known in the art. The first interlayer dielectric 5 may have a thickness greater than about 3000 Ã. . . .

Referring to FIG. 1, a first via 6 may be formed through the first interlayer dielectric 5 to the nitride etchstop layer 4 above the second metal plate 3 by an anisotropic etch process, such as, for example, RIE. Similarly, in various exemplary embodiments, a second via 7 may be formed through the first interlayer dielectric 5 to the nitride etchstop layer 4 above the first metal plate 1 by an anisotropic etch process.

Portions of the nitride etchstop layer 4 may be removed (not shown in FIG. 1), where the first via 6 and the second via 7 contact the nitride etchstop layer 4 above the second metal plate 3 and the first metal plate 1, respectively, by a selective via etch chemistry. The selective via etch chemistry may include a wet etch or a reactive ion etch including any of argon, nitrogen, C⁴F⁸ and argon or oxygen, carbon monoxide, and other via etch chemistries well known in the art, which may remove the nitride etchstop layer without damaging the dielectric layer 2 of the MIM capacitor by either excessive electrical charging or ion/plasma damage.

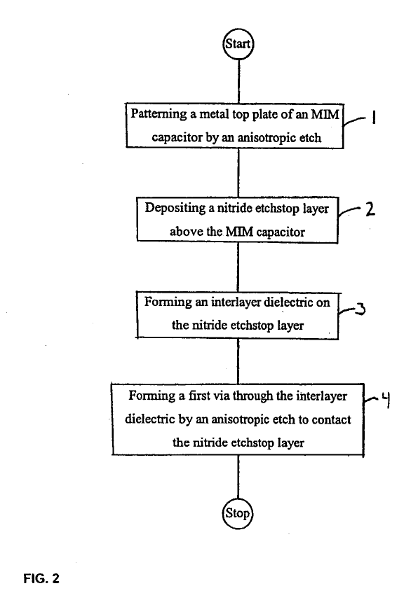

Referring to FIG. 2, a method of fabricating a multilayer semiconductor device, including an MIM capacitor, includes at least the steps of patterning a metal top plate of the MIM capacitor by an anisotropic etch process 1, depositing a nitride etchstop layer above the MIM capacitor 2, forming a first interlayer dielectric on the nitride etchstop layer 3, and forming a first via through the interlayer dielectric by an anisotropic etch process to contact the nitride etchstop layer.

Experimental results indicate that an MIM capacitor, within a multilayer semiconductor device 100, on which a nitride etchstop layer is formed after patterning of the MIM capacitor, possesses superior dielectric properties as measured by time dependent dielectric breakdown. The devices are found to have a tighter distribution of lifetimes under high voltage stress more indicative of intrinsic dielectric breakdown.

The nitride etchstop layer presumably provides a surface above the top plate of the MIM capacitor on which an anisotropic via etch process, for example, RIE, is stopped, thereby, preventing etch-through of the top plate of the MIM capacitor and consequently, plate-to-plate electrical shorting. In addition, that the insulative properties of the nitride etchstop layer presumably prevent excessive electrical charge from reaching the metal plates of the MIM capacitor and consequent dielectric degradation.

The benefits of providing a dielectric layer of the MIM capacitor, which is not subject to dielectric degradation or plate-to-plate electrical shorting, are improved manufacturing yields and enhanced long term reliability.

The nitride layer on top of the MIM capacitor provides a chemical etchstop layer for the via RIE to stop on, thereby, widening the process window for the via RIE process. The via RIE overetch can now be a less controlled process while neither incurring the risk of affecting the reliability of the MIM capacitor nor causing etch-through of the top plate nor allowing for too much erosion of the metal level that the via lands on.

While the invention has been described in terms of exemplary embodiments, those skilled in the art will recognize that the invention can be practiced with modification within the spirit and scope of the appended claims.

Further, it is noted that Applicants' intent is to encompass equivalents of all claim elements, even if amended later during prosecution.

What is claimed is:

1. A multilayer semiconductor device, comprising:
a metal-insulator-metal (MIM) capacitor including a first metal plate, a dielectric layer, and a second metal plate;
a nitride etchstop layer formed above the MIM capacitor;
a first interlayer dielectric formed on the nitride etchstop layer; and
a first via and a second via that extend through at least the first interlayer dielectric to contact the nitride etchstop layer.

2. The multilayer semiconductor device of claim 1, wherein the nitride etchstop layer is deposited directly upon the MIM capacitor.

3. The multilayer semiconductor device of claim 1, wherein the first metal plate and the second metal plate correspond to a bottom plate and a top plate of the MIM capacitor, respectively.

4. The multilayer semiconductor device of claim 3, further comprising a second interlayer dielectric formed between the top plate and the nitride etchstop layer.

5. The multilayer semiconductor device of claim 4, wherein the second interlayer dielectric comprises a thickness of about 1500 Ã . . . to about 10,000 Ã. . . .

6. The multilayer semiconductor device of claim 1, wherein the thickness of the nitride etchstop layer is about 500 Ã . . . to about 1500 Ã. . . .

7. The multilayer semiconductor device of claim 6, wherein a thickness of the nitride etchstop layer is about 700 Ã . . . to about 1200 Ã. . . .

8. The multilayer semiconductor device of claim 1, further comprising a wiring level that is electrically connected to at least one of the first metal plate and the second metal plate.

9. A method of fabricating a multilayer semiconductor device, comprising:
forming an metal-insulator-metal (MIM) capacitor including a first metal plate, a dielectric layer formed on the first metal plate, and a second metal plate formed on the dielectric layer;
patterning the second metal plate;
depositing a nitride etchstop layer above the MIM capacitor;
forming an interlayer dielectric on the nitride etchstop layer;
forming a first via and a second via through at least the interlayer dielectric by an anisotropic etch process to contact the nitride etchstop layer above the patterned second metal plate and above the first metal plate, respectively; and
removing portions of the nitride etchstop layer, where the first via and the second via contact the nitride etchstop layer.

10. The method of claim 9, wherein patterning the second metal plate is accomplished by an anisotropic etch process.

11. The method of claim 9, wherein removing portions of the nitride etchstop layer is accomplished by a selective via etch chemistry that includes any of the group of argon, nitrogen, C⁴F⁸ and argon or oxygen, and carbon monoxide.

12. The method of claim 9, wherein the depositing of the nitride etchstop layer is directly upon the MIM capacitor.

13. The method of claim 9, further comprising patterning at least one of the first metal plate and the dielectric layer by an anisotropic etch process.

14. The method of claim 13, further comprising patterning a wiring level in electrical contact with at least one of the first metal plate and the second metal plate by an anisotropic etch process.

15. The method of claim 9, further comprising forming a second interlayer dielectric between the second metal plate and the nitride etchstop layer.

16. A method of fabricating a multilayer semiconductor device including a metal-insulator-metal (MIM) capacitor, comprising:
patterning a metal top plate of the MIM capacitor by an anisotropic etch process;
depositing a nitride etchstop layer above the MIM capacitor;
forming an interlayer dielectric on the nitride etchstop layer; and
forming a first via through the interlayer dielectric by an anisotropic etch process to contact the nitride etchstop layer.

17. The method of claim 16, further comprising removing a first portion of the nitride etchstop layer above the MIM capacitor, so that, the first via contacts the metal top plate.

18. The method of claim 17, further comprising: forming a second via through the interlayer dielectric by an anisotropic etch process to contact the nitride etchstop layer.

19. The method of claim 18, further comprising removing a second portion of the nitride etchstop layer above the MIM capacitor, so that, the second via contacts a metal bottom plate of the MIM capacitor.

20. The method of claim 16, further comprising forming a second interlayer dielectric between the metal top plate and the nitride etchstop layer.
